(19) United States
(12) Patent Application Publication
(10) Pub. No.: US 2009/0161285 A1
(43) Pub. Date: Jun. 25, 2009

(54) ELECTROSTATIC CHUCK AND METHOD OF FORMING

(75) Inventors: Marc Abouaf, Harvard, MA (US); Stephen W. Into, Harvard, MA (US); Matthew A. Simpson, Sudbury, MA (US)

Correspondence Address: LARSON NEWMAN ABEL & POLANSKY, LLP, 5914 WEST COURTYARD DRIVE, SUITE 200, AUSTIN, TX, 78730, US

(73) Assignee: SAINT-GOBAIN CERAMICS & PLASTICS, INC., Worcester, MA (US)

(21) Appl. No.: 12/338,629

(22) Filed: Dec. 18, 2008

Related U.S. Application Data
(60) Provisional application No. 61/015,604, filed on Dec. 20, 2007.

(51) Int. Cl. H01L 21/683; B05D 3/02

(52) U.S. Cl. 361/234; 427/385.5; 427/386; 427/294

(57) ABSTRACT

An electrostatic chuck includes an insulating layer, a conductive layer overlying the insulating layer, a dielectric layer overlying the conductive layer, the dielectric layer having pores forming interconnected porosity, and a cured polymer infiltrant residing in the pores of the dielectric layer.

### CROSS-REFERENCE TO RELATED APPLICATION(S)

The present application claims priority from U.S. Provisional Patent Application No. 61/015,604, filed Dec. 20, 2007, entitled “Electrostatic Chuck and Method of Forming,” naming inventors Marc Abouaf, Stephen W. Into and Matthew A. Simpson, which application is incorporated by reference herein in its entirety.

### BACKGROUND

1. Field of the Disclosure

This disclosure is directed to an electrostatic chuck (ESC) and is particularly directed to electrostatic chucks for use in processing of flat panel displays.

2. Description of the Related Art

Chucks are used to support and hold wafers and substrates in place within high temperature and corrosive processing chambers such as those used for chemical vapor deposition, physical vapor deposition, or etching. Several main types of chucks have been developed. Mechanical chucks stabilize wafers on a supporting surface by using mechanical holders. Mechanical chucks have a disadvantage in that they often cause distortion of workpieces due to non-uniform forces being applied to the wafers. Thus, wafers are often chipped or otherwise damaged, resulting in a lower yield. Vacuum chucks operate by lowering the pressure between the wafer and the chuck below that of the chamber, thereby holding the wafer. Although the force applied by vacuum chucks is more uniform than that applied by mechanical chucks, improved flexibility is desired. In this respect, pressures in the chamber during semiconductor manufacturing processes tend to be low, and sufficient force cannot always be applied.

Recently, electrostatic chucks (ESCs) have been used to hold workpieces in a processing chamber. Electrostatic chucks work by utilizing a voltage difference between the workpiece and electrodes that can be embedded in the body of the electrostatic chuck, and may apply a more uniform force than mechanical chucks.

Broadly, there exist two types of ESCs: a unipolar type and a bipolar type. The unipolar, or parallel plate ESC includes a single electrode and relies upon plasma used within the processing chamber to form the second “electrode” and provide the necessary attractive forces to hold the substrate in place on the chucking surface. The bipolar, or integrated electrode ESC, includes two electrodes of opposite polarity within the chuck body and relies upon the electric field generated between the two electrodes to hold the workpiece in place.

Additionally, in an ESC, the chucking of a wafer can be achieved using a Coulombic force or Johnsen-Rahbek (JR) effect. Chucks using a JR effect use a resistive layer between the electrode and the workpiece, particularly in workpieces that are semiconductive or conductive. The resistive layer has a particular resistivity, typically less than about 10¹⁰ Ohm-cm, to allow charges within the resistive layer to migrate during operation. That is, during operation of a JR effect ESC, charges within the resistive layer migrate to the surface of the chuck and charges from the workpiece migrate toward the bottom surface thereby generating the necessary attractive electrostatic force. In contrast, ESCs utilizing a Coulombic effect rely upon the embedded electrode as essentially one plate of a capacitor and the workpiece (or plasma) as the second plate of a capacitor, and a dielectric material between the plates. When a voltage is applied across the workpiece and the electrode, the workpiece is attracted to the surface of the chuck.

Despite improvements in ESCs, various industries continue to demand improved performance, for example, those industries processing larger, more massive substrates and workpieces. Notably, the glass industry and particularly the flat panel display (FPD) industry are moving rapidly to produce displays of larger size. Indeed, currently chucks are demanded that have dimensions in excess of two meters by two meters. This shift to processing of larger workpieces, generally within high temperature and corrosive processing environments, places further demands on ESCs used during processing.

### SUMMARY

According to a first aspect, an electrostatic chuck includes an insulating layer, a conductive layer overlying the insulating layer, a dielectric layer overlying the conductive layer, the dielectric layer having pores forming interconnected porosity, and a cured polymer infiltrant residing in the pores of the dielectric layer.

According to another aspect a method of forming an electrostatic chuck includes providing a insulating layer, forming a conductive layer comprising a conductive material overlying the insulating layer, and forming a dielectric layer overlying the conductive layer, the dielectric layer having pores forming interconnected porosity. The method continues with infiltrating the dielectric layer with an infiltrant comprising liquid polymer precursor, and curing the infiltrant, such that cured polymer is left to reside in the pores.

According to yet another aspect, a method of forming an electronic device includes providing a electrostatic chuck defining a work surface, the electrostatic chuck including (i) an insulating layer, (ii) a conductive layer overlying the insulating layer, (iii) a dielectric layer overlying the conductive layer the dielectric layer having pores forming interconnected porosity, and (iv) a cured polymer infiltrant residing in the pores of the dielectric layer. The method further calls for providing a workpiece overlying the work surface, providing a voltage across the electrostatic chuck and the workpiece to maintain the workpiece in proximity to the work surface, and processing the workpiece to form an electronic device.

### BRIEF DESCRIPTION OF THE DRAWINGS

The present disclosure may be better understood, and its numerous features and advantages made apparent to those skilled in the art by referencing the accompanying drawings.

FIG. 1 is a cross-sectional illustration of an electrostatic chuck according to an embodiment.

FIG. 2 is an SEM micrograph illustrating the morphology of a thermally sprayed layer in accordance with an embodiment.

FIG. 3 illustrates a configuration of constituent layers according to an embodiment.

FIG. 4 is a cross-sectional illustration of an electrostatic chuck according to one embodiment.

FIG. 5 is a graph representing infiltrant retention subjected to etch conditions.

The use of the same reference symbols in different drawings indicates similar or identical items.

### DESCRIPTION OF THE EMBODIMENT(S)

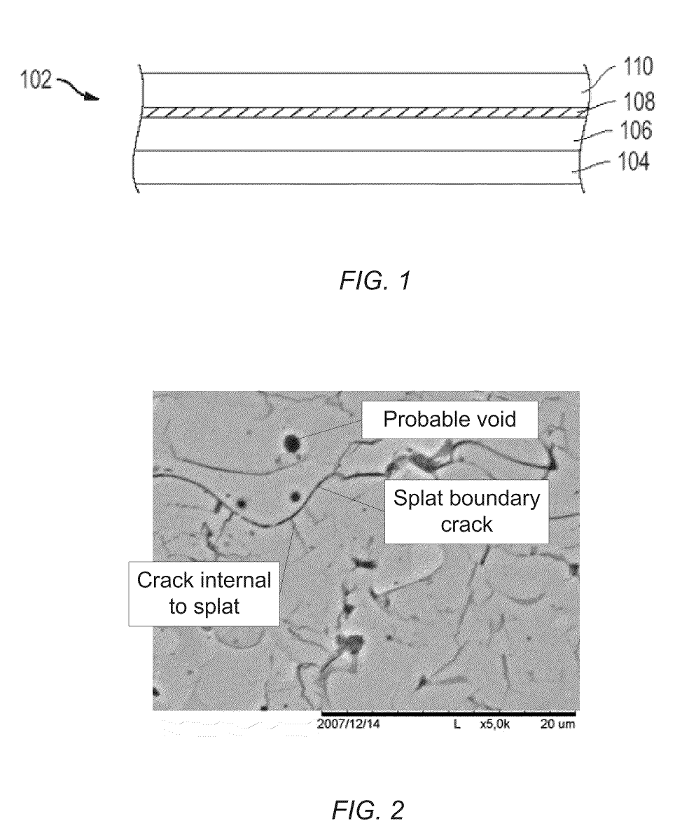

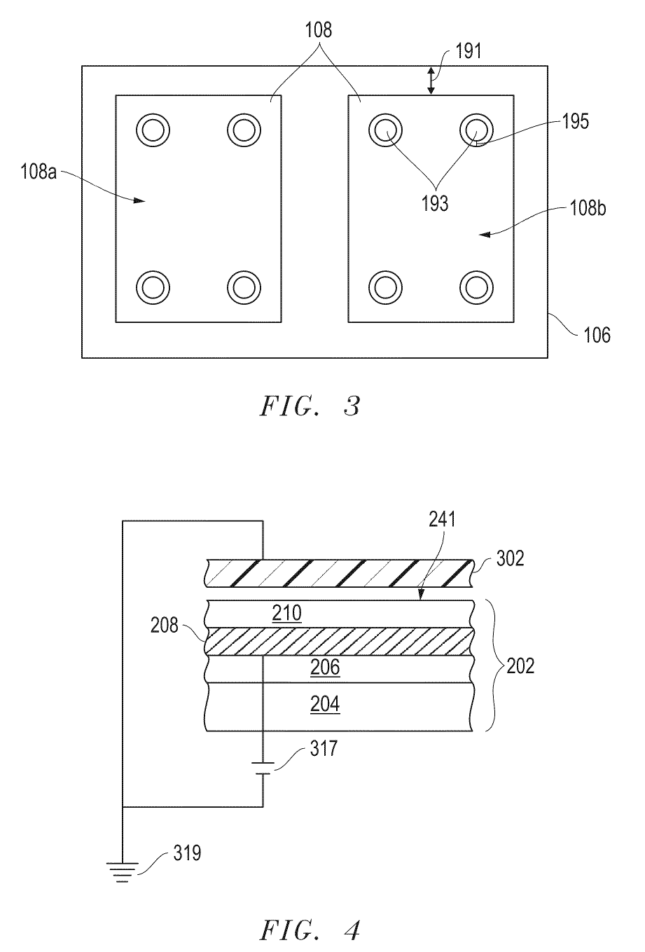

Referring to FIG. 1, an electrostatic chuck 102 is illustrated having several constituent layers. The electrostatic chuck 102 includes a base 104, supporting several layers, an insulating layer 106, a conductive layer 108, and a dielectric layer 110. The base 104 is provided for mechanical support of the overlying layers, and may be chosen from any one of several classes of materials that offer appropriate mechanical characteristics such as stiffness, toughness, and strength, and which can withstand processing temperatures associated with the formation of the overlying layers. Certain embodiments make use of metal alloys, such as iron, nickel or aluminum alloys. Aluminum alloys are particularly suitable.

Although the embodiment shown in FIG. 1 includes a base, self-supporting electrostatic chucks can omit such a structure. However, in the context of large-sized electrostatic chucks utilized in the flat panel display (FPD) industry, generally a base is utilized to provide an appropriate mechanical template for formation of the overlying layers.

The insulating layer can be ceramic-based, typically exhibiting high resistivity values to resist migration of charges from the overlying conductive layer 108 to the base 104, known as leakage current. As used herein, description of a ‘base’ composition generally refers to a base material that accounts for at least 50 weight percent of the layer, typically greater then 60 weight percent, such as greater then 70 or 80 weight percent. According to embodiments, the insulating layer can have a volume resistivity of not less than 10¹¹ ohm-cm, such as not less than about 10¹³ ohm-cm. The insulating layer can have an average thickness greater than about 100 microns, such as greater than about 200 microns. Typically, the thickness of the insulating layer is limited, such as less than 1500 microns. The ceramic-base for forming the insulating layer can include various metal oxide ceramics, such as aluminum-containing oxides, silicon-containing oxides, zirconium-containing oxides, titanium-containing oxides, yttria-containing oxides, and combination or compound oxides thereof. More specifically, embodiments can utilize a material selected from the group consisting of aluminum oxide, zirconium oxide, yttrium oxide, titanates, and silicates (though typically not silica, SiO₂).

According to embodiments of the present invention, the insulating layer is a depositional coating. Depositional coatings include thin-film and thick film coatings. Thin film coatings generally involve deposition of a material atom-by-atom or molecule-by-molecule, or by ion deposition onto a solid substrate. Thin-film coatings generally denote coatings having a nominal thickness less than about 1 micron, and most typically fall within fairly broad categories of physical vapor deposition coatings (PVD coatings), and chemical vapor deposition coatings (CVD coatings), and atomic layer deposition (ALD).

While depositional coatings broadly include both thick and thin film coatings, embodiments herein can take advantage of thick film coatings, such as thermal spray coatings, particularly given the mass and thickness requirements of constituent layers. Thermal spraying includes flame spraying, plasma arc spraying, electric arc spraying, detonation gun spraying, and high velocity oxy/fuel spraying. Particular embodiments have been formed by depositing the layer utilizing a flame spray technique, and in particular, a flame spray technique utilizing the Rokide® process, which utilizes a Rokide® flame spraying spray unit. In this particular process, a ceramic material formed into the shape of a rod is fed into a Rokide® spray unit at a constant and controlled feed rate. The ceramic rods are melted within the spray unit by contact with a flame that is generated from oxygen and acetylene sources, atomized, and sprayed at a high velocity (such as on the order of 170 m/s) onto the substrate surface. The particular composition of the ceramic rod can be chosen based on dielectric and resistivity properties. According to the Rokide® process, fully molten particles are sprayed onto the surface of the substrate, and the spray unit is configured such that particles are not projected from the spray unit until being fully molten. The kinetic energy and high thermal mass of the particles maintain the molten state until reaching the substrate.

Further, the insulating layer can be porous, particularly having interconnected porosity, such as a porosity within a range of about 2% to 10% by volume. In the particular case of a thermally sprayed insulating layer, this porosity may be defined by the splat formations that are characteristic to the thermal spray process. Particularly, the pores can be interconnected and extend between the splat formations. In this respect, reference is made to FIG. 2 showing an SEM photograph of a thermally sprayed alumina layer, which has a porosity of about 5 vol. %. As can be seen, pores are defined between the splat formations, and the pores are interconnected through channels extending along splat lines.

The conductive layer 108 can also be a depositional coating as described above. Certain embodiments call for a thick film deposition process such as printing or a spraying (e.g., thermal spraying). As above, in the context of a thermal spraying process, plasma spraying or wire gun spraying may be utilized. In connection with an underlying thermally sprayed insulating layer, the conductive layer 108 is desirably thermally sprayed as well.

The conductive layer 108 is generally thinner relative to the insulting layer 106. According to one embodiment, the conductive layer 108 has an average thickness of not greater than about 100 microns, such as not greater than about 75 microns, and in some cases not greater than about 50 microns. In one particular embodiment, the conductive layer 108 has an average thickness within a range of between about 10 microns and about 50 microns.

In reference to the materials suitable for forming the conductive layer 108, generally the conductive layer 108 is formed of a conductive material, particularly inorganic materials, such as a conductive metal, or metal alloy. Suitable metals can include high temperature metals such as titanium, molybdenum, nickel, copper, tungsten, iron, silicon, aluminum, noble metals and combinations or alloys thereof. In one particular embodiment, the conductive layer 108 includes molybdenum, tungsten or a combination thereof. Moreover, particular embodiments utilize a conductive layer 108 having not less than about 25 wt % metal, such as not less than about 50 wt % metal. According to another embodiment, the conductive layer 108 includes not less than about 75 wt % metal, such as not less than about 90 wt % metal, and even in some instances, the conductive layer 108 is made entirely of metal. The foregoing description of metal includes elemental metals and metal alloys.

The conductive layer 108 can be a composite material, and as such, in addition to the conductive material, the conductive layer 108 can contain adhesion promoters. Such adhesion promoters can be inorganic materials. Particularly suitable adhesion promoters can include oxide-based materials, such as yttrium oxide, aluminum oxide, zirconium oxide, hafnium oxide, titanium oxide, chromium oxide, iron oxide, silicon oxide, barium titanate, tantalum oxide, barium oxide, or compound oxides thereof. According to one particular embodiment, a suitable adhesion promoter contains material species of the underlying layer and/or overlying layer.

Adhesion promoters are generally present within the conductive layer 108 in an amount of less than about 75 vol %. The amount of adhesion promoter can be less, such that the conductive layer 108 contains not greater than about 50 vol %, such as about 25 vol %. In one embodiment, the conductive layer 108 is formed via a thermal spraying process during which the adhesion promoter material is provided simultaneously with the conductor material (e.g., a metal). In one particular embodiment, the conductive layer 108 is formed via a spraying process that utilizes a composite powder composition, which includes the conductor material and the adhesion promoter.

In reference to the electrical properties of the conductive layer 108, the sheet resistance of the conductive layer 108 according to one embodiment is not greater than about 10⁶ ohms, such as not greater than about 10⁴ ohms. According to another embodiment, the sheet resistance of the conductive layer 108 is within a range of between about 10¹ ohms and about 10⁶ ohms.

In further reference to the conductive layer 108, it is generally a continuous layer, conformally deposited over the insulating layer 153 or the insulating layer 106. According to one embodiment, the conductive layer 108 is a substantially continuous layer of material. To clarify, the description of ‘substantially continuous’ means that the majority of the surface that is used to attract the workpiece is covered by a conducting surface, which may have pores in it of a size approximately equal to or smaller than the dielectric thickness. That is, small holes can be present in the layer, which can appear in embodiments with high percentages of adhesion promoter, for example, such holes not appreciably affecting chucking force.

Alternatively, the conductive layer 108 can form two isolated regions to respectively form a cathode region 108a and an anode region 108b as shown in FIG. 1G. Further, the conductive layer 108 can include a pattern which accommodates features 193 within the layer and extending through the layers, such features can include cooling holes, perforations for facilitating dechucking, electrical contacts, and the like. Notably, the conductive layer 108 can be patterned to provide suitable spacing 195 from such features. According to one embodiment, such spacing is generally greater than about 0.5 mm, such as greater than about 1.0 mm, or even, greater than about 2.0 mm.

The conductive layer 108 can be configured so as to terminate before reaching the edge of the insulating layer 106, which construction may be advantageous to maintain dielectric properties. As such, the conductive layer 108 can be spaced from the edge of the chuck such that a space 191 extends between the edge of the chuck and the conductive layer and extends around the periphery of the conductive layer 108. The average width of this space may be generally greater than about 0.5 mm, such as greater than about 1.0 mm, or even greater than about 2.0 mm.

Turning to the dielectric layer, the dielectric layer can be ceramic-based as well. Such ceramic-based materials include metal oxides, including aluminum-containing oxides, silicon-containing oxides, zirconium-containing oxides, yttria-containing oxides, and insulating titanium-based oxides. In particular, the dielectric material may be selected from the group consisting of aluminum oxide, zirconium oxide, yttrium oxide titanates, and silicates (excluding silica). The dielectric layer can be in the form of thick-film having a thickness not less than about 50 microns, such as not less than about 100 microns, or not less than 200 microns. Certain embodiments have a maximum thickness of about 500 microns. According to a particular feature, the dielectric layer is porous, having pores that form interconnected porosity. That is, the dielectric layer has a network of pores extending into and oftentimes throughout the interior of the body of the dielectric layer, and be accessible from external pores of the dielectric material. The porosity level of the dielectric layer can vary, such as not less than about 1 vol %, oftentimes, not less than about 2 vol %. Suitable porosity ranges can be within a range of about 2 vol. % to 10 vol. %. The pore size of the pores in the dielectric layer is notably fine, generally in the nanometer range. For example, the dielectric layer may have an average pore size of not greater than about 200 nm, such as not greater than about 100 nm.

Generally, optimal chucking properties can be achieved by utilizing a dielectric material having a high dielectric constant (high-k material). As such, the dielectric constant k is generally not less than about 5, such as not less than about 10.

Embodiments may utilize even higher dielectric constants, such as not less than about 15, or not less than about 20. Further, embodiments herein provide a dielectric layer having a dielectric strength per unit thickness greater than 10 V/micrometer, and in certain cases greater than 12 V/micrometer, greater than 15 V/micrometer, and even greater than 20 V/micrometer.

According to embodiments of the present invention, the dielectric layer, like the insulating layer, is a depositional coating. Depositional coatings include thin-film and thick film coatings. However, embodiments herein generally utilize thick film coatings, such as thermal spray coatings, given the mass and thickness requirements of constituent layers. Thermal spraying includes flame spraying, plasma arc spraying, electric arc spraying, detonation gun spraying, and high velocity oxy/fuel spraying. Particular embodiments have been formed by depositing the layer utilizing a flame spray technique, and in particular, a flame spray technique utilizing the Rokide® process as described above.

As described above in connection with the insulating layer, the thermally sprayed dielectric layers can be characterized as having particular splat formations, again, reference is made to FIG. 2. In the case of a thermally sprayed dielectric layer, the pores are present between splat formations, and are interconnected with each other along splat lines between individual splat formations and via cracks in the splats themselves.

According to a particular development, the electrostatic chuck 102 is subjected to an infiltration process. Particularly, the electrostatic chuck body is subjected to infiltration with a low viscosity polymer precursor, such as an oligomer or monomer composition provided in a liquid carrier. According to a particular feature, the polymer precursor has a desirably low viscosity, enabling wetting and a high degree of penetration into the interconnected fine porosity of at least the dielectric layer, and optionally the insulating layer. Based on practical studies, the polymer precursor penetrates at least 50 vol % of the porosity, such as at least 65 vol %. As stated above, embodiments may have a particularly fine porous structure, having an average pore size less than 200 nm, such as less than 100 nm. Accordingly, the viscosity of the polymer precursor is typically not greater than 1000 centipoise (cP). Generally, the polymer precursor has a viscosity not greater than 500 cP, such as not greater than 200 cP. Indeed, particular working examples have viscosities less than 100 cP, and even less than 50 cP. Polymer precursors used in accordance with examples provided below, have viscosities on the order of 10 to 30 cP.

Additionally, it is desired that the infiltrant formed of the liquid polymer precursor has desirably low shrinkage upon solvent volatilization or vaporization, and curing. Typically, it is desired that the shrinkage from the liquid precursor state to the solid cured state is not greater than 20 vol. %, such as not greater than 15 vol. %, or not greater than 10 vol. %. Reduced shrinkage rates help improve degree of filling of the interconnected porous structure, leaving behind minimized open and unfilled spaces. Based on penetration efficiency and shrinkage, typically at least 40 vol %, such as at least 50 vol % of the pore volume is filled with cured polymer infiltrant. Enhanced filling may be achieved, such as on the order of at least 60 vol %, and in certain embodiments, at least 65 vol % or 70 vol %. For clarity, it is noted that the porosity information provided above for the dielectric layer corresponds to pore volume percentage, ignoring the infiltrant content, that is, prior to infiltration. Pore volume percentages, adjusted for the combination of dielectric material combined with cured polymer infiltrant, are of course lower. For example, a dielectric layer having a porosity of 4 vol %, infiltrated at a loading level of 60% of the pore volume with infiltrant, would have a total or composite porosity of 1.6 vol %. The foregoing is provided for clarification only, and unless otherwise stated, pore volume percentages refer to the as-formed layers prior to infiltration. Thus, in the case of the dielectric layer, the pore volume percentage values are relative to the dielectric ceramic material, not the overall porosity of the dielectric layer. Similarly, in the case of the insulating layer, the pore volume percentage values are relative to the insulating ceramic material, not the overall porosity of the insulating layer.

Liquid polymer precursors may be selected from various polymer families, including acrylates, urethanes and selected epoxy resins. Particular embodiments make use of low viscosity methyl acrylates. The polymer precursors may be cured by actinic radiation or thermally, although thermal curing is desired to enable complete curing of interior regions of the liquid polymer precursor that actinic radiation cannot reach.

Infiltrating may be initiated by simply coating, such as by spraying or brushing, or otherwise immersing the electrostatic chuck in the liquid polymer precursor. Continued processing typically involves subjecting the thus coated or immersed electrostatic chuck to a vacuum, thereby further enhancing pore penetration. Vacuum environments can improve removal of trapped gases in the dielectric layer. Use of a vacuum may be done prior to curing, or simultaneously with curing, such as in a vacuum chamber while heating the thus coated electrostatic chuck. Multiple pumping cycles can be carried out, cycling between a low pressure vacuum environment and atmospheric pressure to enhance penetration. Typical vacuum pressure are on the order of less than 0.25 atm, such as less than 0.1 atm.

In the case of thermal curing, typical thermal cure temperatures generally exceed to 40° C., such as within a range of 50° C. to 250° C. Thermal cure dwell times can range from 5 hours and up. Typically, desirable curing is achieved by 40 hours. Typical cure time periods extend from 10 hours to 30 hours. from Depending on the particular curing agent and polymer system, oxygen may be evacuated during curing, to further improve reaction kinetics and promote complete curing of the precursor. Oxygen partial pressures are generally kept below 0.05 atm, such as less than 0.02 atm.

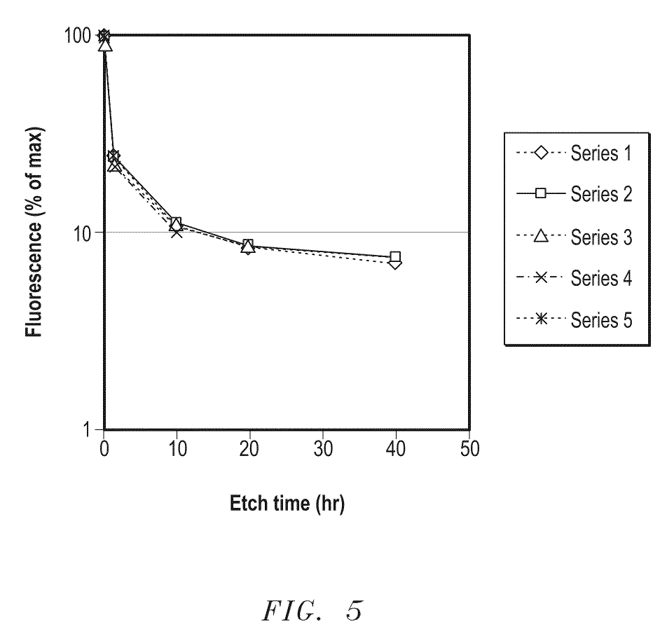

Referring to FIG. 4, a cross-sectional diagram of an electrostatic chuck according to a particular embodiment is illustrated. The chuck includes a base 204 and an insulating layer 206 overlying the base 204. The electrostatic chuck further includes a conductive layer 208 overlying the insulating layer 206, and dielectric layer 210 overlying the conductive layer 208. As also illustrated, a workpiece 302 is being chucked to the working surface 241 of the electrostatic chuck 202. Such a workpiece can be an insulating workpiece such as glass, and particularly a glass panel being processed for a display.

In further reference to FIG. 4, a direct current source 317 is connected to a ground. Notably, the direct current source 317 is connected to the conductive layer 208 and provides the bias necessary to create a capacitor between the conductive layer 205 and the workpiece 302. It will be appreciated that the chucking force will require the utilization of a plasma or other charge source, such as ion or electron gun, within the processing chamber to provide the necessary conductive path to the surface of the workpiece, in order to generate attractive forces to hold the workpiece 302 in place on the chucking surface.

It will be appreciated that while FIG. 2 illustrates a cross-sectional view of the layers, provision of contacts between the conductive layer 208 and cooling channels can be implemented within the electrostatic chuck provided herein. Generally, cooling channels accommodate cooling of the work piece by providing pathways for a cooling gas through the electrostatic chuck to the back surface of the work piece. Such cooling channels can extend through the layers of the ESC, such as from the substrate through to the top surface. Generally, the cooling gas includes an unreactive gas of high thermal conductivity, such as helium.

The present disclosure also provides a method of forming an electronic device using an electrostatic chuck as described in embodiments herein. Here, the chucked workpiece assembly shown in FIG. 4 is provided within the processing chamber. The workpiece can generally include an inorganic material and particularly is formed principally of a glass phase, such as a silicate-based glass. According to one embodiment, the workpiece is a display panel, intended for final application as a video display. Such video displays can include liquid crystal displays (LCDs), plasma displays, electroluminescent displays, displays utilizing thin-film-transistors (TFTs), and the like. Other workpieces can include semiconductor wafers, such as silicon-based wafers.

Generally, the workpieces can be large and in some cases, have rectangular shape (including square), with length and width dimensions not less than about 0.25 m, such as not less than about 0.5 m or even not less than about 1.0 m. The electrostatic chuck can be similarly sized, and indeed have a working surface of a generally rectangular contour and having a surface area not less than 3 m².

Processing of the workpiece can include chemical processing, such as a photolithography and chemical processing, and more particularly can include a masking, etching, or deposition process, or a combination of all such processes. In one embodiment, processing of the workpiece includes etching, such as a plasma etching process. According to another embodiment, processing of the workpiece includes a thin-film deposition process, such as one utilizing a vapor deposition process, such as chemical vapor deposition (CVD), and particularly a plasma assisted CVD process.

According to one embodiment, processing of the workpiece includes forming electronic devices on the workpiece, such as transistors, and more particularly, processing of the workpiece includes forming a series of transistors, or an array of transistors, such as a TFT. As such, the workpiece can undergo multiple masking, deposition and etching processes. Moreover, such a process can include deposition of metals, semiconductive materials, and insulating materials.

Generally, such processing is undertaken at reduced pressures, and according to one embodiment, processing of the workpiece is done at a pressure of not greater than about 0.5 atm, such as not greater than about 0.3 atm, or not greater than about 0.1 atm.

### EXAMPLES

The following examples based are based on coupons samples to illustrate concepts of present invention. It is understood that commercial samples would be in the form of completed electrostatic chucks having the requisite features for usage.

### Example 1

### Comparative Samples, No Infiltration

Four 6061 aluminum squares 4 cm on a side were grit blasted, plasma sprayed with aluminum oxide to a thickness of about 500 um to provide a porosity about 5%, and then plasma sprayed with tungsten on top to a thickness of about 50 um.

The samples were tested by applying a steadily increasing DC voltage between the tungsten and the base aluminum and monitoring current. Breakdown was deemed to occur when the current exceeded 2 mA.

TABLE 1

| Comparative Sample | Breakdown voltage (kV) |
|---|---|
| H | 2.5 |
| K | 10.3 |
| N | 4.7 |
| O | 2.1 |

The breakdown voltage varies, with a mean value of only 4.9 kV

### Example 2

### Samples with Infiltration

Three samples were prepared as for example 1, but with the following addition. HL-126 acrylate monomer (obtained from Permabond LLC of Pottstown, Pa.) was painted onto the surface after spraying. Generous amounts were applied, so that the surface looked well wetted even after a minute or so was allowed for the liquid to soak into the pores. The samples were placed into a vacuum oven and several cycles of evacuation followed by backfill with argon were conducted. This served two purposes: the HL-126 was driven further into the pores and oxygen (which inhibits the cure of the monomer) was removed from the oven.

Samples were cured for about 2 hours at 120° C. They were then removed from the oven and an area over the tungsten was ground clean so that electrical contact could be established to the tungsten. The samples were then tested as in Example 1, with a maximum applied voltage of 10 kV.

In no case did breakdown occur, indicating the average breakdown voltage exceeds 10 kV.

### Example 3

### Additional Characterization

An important attribute of the infiltration process is that infiltrant not be removed by plasma gases. It was found unexpectedly that the infiltrant stays intact for a long time under etch conditions.

A set of coupons was plasma sprayed with yttrium oxide to a thickness of 100 um using a process that produces 4-5% porosity. They were infiltrated with HL-126 as described in Example 2 above.

The coupons were etched in a March PM-600 plasma asher (March Plasma Systems Inc., Concord, Calif.), with oxygen at 300W, 250 millitorr for extended times. The amount of infiltrant was determined by monitoring its fluorescence intensity.

FIG. 5 shows that, after a short initial transient (corresponding to removal of HL-126 from the surface), the infiltrant remains in the pores of the coating for an extended period of time.

The unexpected retention of infiltrant is not believed to be due to material properties of the infiltrant (which etches relatively easily as shown by the initial loss of fluorescence), but rather is determined by the pore structure of the plasma spray coating. The pores are so fine and tortuous that plasma gases cannot get penetrate the cured infiltrant extending into the body of the alumina layer to attack the infiltrant.

### Example 4

### Comparison of Methylacrylate and Epoxy Infiltrants

Both yttria and alumina coatings were formed on aluminum substrates for further evaluation of polymer infiltrants. Yttria coatings were formed utilizing a yttria raw material having particle size within a range of 17-60 microns under the following conditions: torch current of 600 A, argon flow of 25 slm, hydrogen flow of 3.5 slm, helium flow of 35 slm, standoff of 100 mm and a feed rate of 20 g/min. Similarly, alumina coatings were formed from a raw material having a particle size within a range of 15 to 38 microns under the following conditions: a torch current of 600 A, argon flow of 35 slm, hydrogen flow of 13 slm, helium flow of 0 slm, 110 mm standoff and a fee rate of 20 g/min.

The various coated substrates were then subjected to coating processes. Here, methylacrylate HL126 liquid was applied onto the yttria and alumina coatings. A vacuum was pulled on the entire sample, and the application and vacuum process was repeated until the surface remained wet, indicating full infiltration into the coating. The methylacrylate was cured at 140° C. in an inert environment for 2.5 hours, and excess methylacrylate on the coating surface was removed.

Epoxy coating was carried out by pre-heating the yttria and alumina coated samples to 40° C., and applying epoxy liquid onto the coating surface. A vacuum was pulled over the entire sample and the application/vacuum process was repeated until the surface remained wet, indicating full infiltration into the coating. The epoxy was cured at 60° C. in an inert environment for 48 hours and excess epoxy was removed after curing. The polymer infiltrant properties are summarized below in Table 2.

TABLE 2
Infiltrant Properties

| | Methacrylate | Epoxy |
|---|---|---|
| Viscosity (cps) | 12 | 60 at 40° C. |
| Curing Shrinkage (%) | ~10 | <3 |
| Cure Temp (° C.) | 140 | 60 |
| Substrate Warpage | Moderate | Low |

The thus coated and infiltrated samples were then characterized as summarized below in Table 3.

TABLE 3
Coating Properties

| | Y₂O₃ Coating | | | Al₂O₃ Coating | |
|---|---|---|---|---|---|
| | As- | Methacrylate | Epoxy | As- | Epoxy |
| | Sprayed | Sealed | Sealed | Sprayed | Sealed |
| Coating Thickness (mm) | 201 | 235 | 200 | 533 | 544 |
| Coating Porosity (%) | 3-4 | | | 4-5 | |
| Dielectric Strength (V/mil) | 717 | 1115 | 1013 | 335 | 635 |
| Resistivity (ohm-cm) | 5.8E+11 | 9.5E+13 | 1.6E+14 | 3.0E+10 | 2.9E+14 |

The coating thickness values are based upon Eddy Current analysis. Coating porosity was measured by image analysis. Dielectric strength and resistivity were measured according to ASTM D3755 and ASTM D257, respectively.

As summarized above, both the methylacrylate and epoxy samples showed marked improvement in performance of the substrate, characterized by notably enhanced dielectric strength. However, it is noted that the epoxy samples cured at lower temperatures demonstrated reduced substrate warpage, and as such, may be desirable for particular applications. Additionally, testing was done on room temperature, solvent-based infiltrants, particularly Dichtol 1532. It was found that solvent-based cured infiltrants generally have notable curing shrinkage associated with volatilization of the solvent. It was found that such infiltrants only provided moderate improvements in dielectric strength relative to the thermally cured infiltrants such as acrylates and epoxies. Accordingly, thermally curable infiltrants may be particularly useful for certain applications.

As should be clear based on the disclosure herein, particular embodiments are drawn to electrostatic chucks that have at least one porous layer having pores forming interconnected porosity. That layer, generally at least the dielectric layer, contains a cured polymer infiltrant that surprisingly improves dielectric breakdown properties of the layer. The foregoing approach is in direct contrast to state of the art approaches that focus on 100% dense layers for proper dielectric functionality. Without wishing to be tied to any particular theory, it is believed that the cured infiltrant remaining in the interconnected porosity reduces charge flow along interior pore surfaces, which contribute to poor dielectric properties in porous dielectric materials.

In addition, it has been found that embodiments demonstrate improved mechanical robustness, as use of porous layer(s), even when infiltrated with a cured polymer infiltrant, are less susceptible to failure based on induced strain, such as due to thermal expansion mismatches between the layer(s) and an underlying base, for example.

While the invention has been illustrated and described in the context of specific embodiments, it is not intended to be limited to the details shown, since various modifications and substitutions can be made without departing in any way from the scope of the present invention. For example, additional or equivalent substitutes can be provided and additional or equivalent production steps can be employed. As such, further modifications and equivalents of the invention herein disclosed may occur to persons skilled in the art using no more than routine experimentation, and all such modifications and equivalents are believed to be within the scope of the invention as defined by the following claims.

1. An electrostatic chuck comprising:
an insulating layer;
a conductive layer overlying the insulating layer;
a dielectric layer overlying the conductive layer, the dielectric layer comprising pores forming interconnected porosity; and
a cured polymer infiltrant residing in at least a portion of the pores of the dielectric layer.

2. The electrostatic chuck of claim 1, wherein the dielectric layer has a porosity of not less than 1 vol %.

3-4. (canceled)

5. The electrostatic chuck of claim 1, wherein the dielectric layer has an average pore size of not greater than 200 nm

6. (canceled)

7. The electrostatic chuck of claim 1, wherein the dielectric layer is comprised of a thermally sprayed layer having splat formations, the pores being interconnected and extending between the splat formations or through cracks present in the plat formations.

8. The electrostatic chuck of claim 1, wherein the dielectric layer has a dielectric constant not less than about 5.

9. The electrostatic chuck of claim 1, wherein the dielectric layer comprises a dielectric material selected from the group consisting of aluminum-containing oxides, silicon-containing oxides, zirconium-containing oxides, titanium-containing oxides, yttria-containing oxides, and combinations or compound oxides thereof.

10-11. (canceled)

12. The electrostatic chuck of claim 1, wherein the dielectric layer has a volume resistivity of not less than about 10¹¹ Ohm-cm.

13. (canceled)

14. The electrostatic chuck of claim 1, wherein the insulating layer comprises a material selected from the group consisting of aluminum-containing oxides, silicon-containing oxides, zirconium-containing oxides, titanium-containing oxides, yttria-containing oxides and combinations or compound oxides thereof.

15-16. (canceled)

17. The electrostatic chuck of claim 1, wherein the insulating layer is comprised of a thermally sprayed layer having splat formations, the pores being interconnected and extending between the splat formations or through cracks present in the plat formations.

18. (canceled)

19. The electrostatic chuck of claim 1, wherein the conductive layer comprises a sheet resistance of not greater than about 10⁶ Ohms.

20. The electrostatic chuck of claim 1, wherein the conductive layer comprises a metal selected from the group of metals consisting of titanium, molybdenum, nickel, copper, tungsten, silicon, and aluminum, noble metals and combinations and metal alloys thereof.

21. (canceled)

22. The electrostatic chuck of claim 1, wherein the electrostatic chuck has a surface area not less than about 3 m².

23. The electrostatic chuck of claim 1, wherein the cured polymer infiltrant is selected from the group consisting of acrylates, urethanes, and epoxy resins.

24. The electrostatic chuck of claim 23, wherein the cured polymer infiltrant comprises epoxy resin.

25. The electrostatic chuck of claim 1, wherein the cured polymer infiltrant comprises a thermally cured polymer.

26. The electrostatic chuck of claim 1, further wherein the cured polymer infiltrant has a volume shrinkage not greater than 20 vol % upon curing.

27. The electrostatic chuck of claim 1, wherein the dielectric layer has a dielectric strength per unit thickness greater than 10 V/micrometer.

28-30. (canceled)

31. The electrostatic chuck of claim 1, wherein the cured polymer infiltrant occupies at least 40 vol % of the total pore volume of the dielectric layer.

32-33. (canceled)

34. An electrostatic chuck comprising:
an insulating layer;
a conductive layer overlying the insulating layer;
a dielectric layer overlying the conductive layer, the dielectric layer having a porosity not less than 2 vol %, wherein the dielectric layer has a dielectric strength per unit thickness greater than 10 V/micrometer.

35. A method of forming an electrostatic chuck comprising:
providing a insulating layer;
forming a conductive layer comprising a conductive material overlying the insulating layer;
forming a dielectric layer overlying the conductive layer, the dielectric layer comprising pores forming interconnected porosity;
infiltrating the dielectric layer with an infiltrant comprising liquid polymer precursor; and
curing the infiltrant, such that cured polymer is left to reside in at least a portion of the pores.

36. The method of claim 35, wherein the cured polymer infiltrant is selected from the group consisting of acrylates, urethanes, and epoxy resins.

37. (canceled)

38. The method of claim 35, wherein the liquid polymer precursor has a viscosity of not greater than 500 cP.

39-40. (canceled)

41. The method of claim 35, wherein curing is carried out thermally, at a temperature of at least 50° C.

42. The method of claim 35, wherein infiltrating includes exposing the dielectric layer to a vacuum at a pressure not greater than 0.25 atm.

43-46. (canceled)

47. A method of forming an electronic device comprising:
providing an electrostatic chuck defining a work surface, the electrostatic chuck comprising (i) an insulating layer, (ii) a conductive layer overlying the insulating layer, (iii) a dielectric layer overlying the conductive layer the dielectric layer having pores forming interconnected porosity, and (iv) a cured polymer infiltrant residing in the pores of the dielectric layer;
providing a workpiece overlying the work surface;
providing a voltage across the electrostatic chuck and the workpiece to maintain the workpiece in proximity to the work surface; and
processing the workpiece to form an electronic device.

48-52. (canceled)
